(19) United States
(12) Patent Application Publication
(10) Pub. No.: US 2026/0368384 A1
(43) Pub. Date: Nov. 19, 2026

(54) Method, Apparatus and Device for Estimating a Center of Gravity of Flight Passengers

(71) Applicant: TRAVELSKY TECHNOLOGY LIMITED, Beijing (CN)

(72) Inventors: Wenxiao LI, Beijing (CN); Yang LI, Beijing (CN); Zheng CHEN, Beijing (CN); Zhongxing ZHAO, Beijing (CN); Yue HAN, Beijing (CN); Yazhong LIANG, Beijing (CN); Bingqian NIU, Beijing (CN); Yulong ZHANG, Beijing (CN); Chao LI, Beijing (CN); Xinran LI; Meng YU, Beijing (CN); Yuanqing ZUO, Beijing (CN)

(21) Appl. No.: 19/108,995

(22) PCT Filed: Aug. 9, 2023
(86) PCT No.: PCT/CN2023/111945

§ 371 Date: Mar. 5, 2025

(30) Foreign Application Priority Data
Sep. 5, 2022 (CN) 202211076577.1

(51) Int. Cl. G06F 30/15

(52) U.S. Cl. CPC G06F 30/15

(57) ABSTRACT

A method, apparatus and device for estimating the center of gravity of flight passengers including the following steps: passenger data, cabin layout information and a passenger weight table of a to-be-measured flight are obtained; a weight of a passenger, and a center of gravity influence index of the passenger; a seat is allocated to a passenger who does not complete seat selection, and a seat row number of the passenger who does not complete seat selection is obtained; a weight of the passenger who does not complete seat selection is determined, and a center of gravity influence index of the passenger who does not complete seat selection is computed, the weight and a center of gravity index of a selected seat row of the passenger who does not complete seat selection; and the center of gravity of the passengers of the to-be-measured flight is computed.

### CROSS-REFERENCES TO RELATED APPLICATIONS

The present disclosure is a National Stage of International Patent Application No: PCT/CN2023/111945 filed on Aug. 9, 2023 which claims the priority to Chinese Patent Application No. 202211076577.1, filed on Sep. 5, 2022 and entitled “Method and apparatus for estimating a center of gravity of flight passengers”, the entire contents of each of which is incorporated herein by reference.

### TECHNICAL FIELD

The present disclosure relates to the field of aviation information, and particularly relates to a method, apparatus and device for estimating a center of gravity of flight passengers.

### BACKGROUND

High security is a basic premise and an important guarantee for an aircraft to take off on time, reflecting the lofty mission and responsibility of the civil aviation industry. As a core link to ensure high security, aircraft loading and balancing can effectively control a position of a center of gravity of an aircraft by rationally allocating passenger seats and cargo cabins. Thus, the center of gravity of the aircraft is located within a range of the secure center of gravity, such that flight security of the aircraft will be ensured.

It is a critical step to compute the center of gravity of flight passengers in a computation process of the center of gravity of the aircraft. An apparatus for estimating the center of gravity of passengers of a loaded flight is used to estimate the center of gravity of the passengers without passenger data fully obtained. It is a crucial support and an effective guarantee for on-time flight departure. An aircraft loading operation generally begins a while before flight departure. In this process, various unknown states of flight passengers are possible, for example, the passenger reserves a seat during ticket purchase but fails to check in or fails to reserve a seat during ticket purchase. A case that a passenger does not complete seat selection or does not check in indicates uncertainty of a seat finally selected by the passenger. In the meantime, the aircraft will allocate and load cargoes from a freight system simultaneously. In this case, the center of gravity of the passengers serves as an important basis of a cargo allocation solution in a cargo hold. Computation of the center of gravity of the passengers is mainly related to weights of the passengers and seat rows where the passengers are located. If the center of gravity is computed after all the passengers check in, an inevitable delay in loading cargoes will be caused, leading to a delay of the aircraft.

It is impossible to estimate the center of gravity of a passenger flight in a current flight loading process, so only preliminary computation can be conducted based on obtained passenger data. Then, the cargoes can be loaded according to the computation result and previous experience. Finally, after all the passengers complete check-in, if the center of gravity needs to be adjusted, it will be corrected by adjusting cargo positions in the cargo hold. This method may cause certain cargo adjustment demand due to the lack of estimation of the center of gravity of the passengers. The more accurately the center of gravity of the passengers is estimated, the better the cargo loading solution of the cargo hold will be. Thus, a probability of adjusting the center of gravity by adjusting the cargoes will be greatly reduced.

In view of that, it is a pressing issue to accurately estimate the center of gravity of the flight passengers in this field.

### SUMMARY

The present disclosure provides a method, apparatus and device for estimating a center of gravity of flight passengers.

To achieve the objective, the present disclosure provides the following technical solution: a method for estimating a center of gravity of flight passengers includes the following steps: passenger data, cabin layout information and a passenger weight table of a to-be-measured flight are obtained, where the passenger data includes passenger attribute and seat attribute of each of the passengers; type of each of the passengers includes a passenger who completes seat selection and a passenger who does not complete seat selection; the seat attribute includes a seat row number of the passenger who completes seat selection; the seat row number indicates a seat row selected by the passenger; the cabin layout information includes a center of gravity index of each of the seat rows; and the passenger weight table includes a weight of a passenger corresponding to each of the passenger attributes; and types of the passenger attribute comprise an adult passenger, a male passenger, a female passenger, a child passenger, and an infant passenger;
a weight of the passenger who completes seat selection is determined based on the passenger weight table and the passenger attribute of the passenger who completes seat selection, and a center of gravity influence index of the passenger who completes seat selection is computed based on the seat row number, the weight and the center of gravity index of a selected seat row of the passenger who completes seat selection;
a seat is allocated to the passenger who does not complete seat selection, and a seat row number of the passenger who does not complete seat selection is obtained;
a weight of the passenger who does not complete seat selection is determined based on the passenger weight table and the passenger attribute of the passenger who does not complete seat selection, and a center of gravity influence index of the passenger who does not complete seat selection is computed based on the seat row number, the weight and the center of gravity index of a selected seat row of the passenger who does not complete seat selection; and
a center of gravity of the passengers of the to-be-measured flight is computed based on the center of gravity influence index of the passenger who completes seat selection and the center of gravity influence index of the passenger who does not complete seat selection.

One embodiment of this application, the passenger who completes seat selection includes a checked-in passenger.

The steps that a weight of the passenger who completes seat selection is determined based on the passenger weight table and the passenger attribute of the passenger who completes seat selection, and a center of gravity influence index of the passenger who completes seat selection is computed based on the seat row number, the weight and the center of gravity index of a selected seat row of the passenger who completes seat selection include the following steps: a weight of the checked-in passenger is obtained from the passenger weight table according to the passenger attribute of the checked-in passenger, and the center of gravity influence index of the checked-in passenger is computed based on the seat row number of the checked-in passenger, the weight of the checked-in passenger and the center of gravity index of a selected seat row of the checked-in passenger.

One embodiment of this application, the passenger who completes seat selection further includes a passenger who does not check in but completes seat selection.

After the center of gravity influence index of the checked-in passenger is computed, the method further includes the following steps:
a weight of the passenger who does not check in but completes seat selection is obtained from the passenger weight table according to the passenger attribute of the passenger who does not check in but completes seat selection, and the center of gravity influence index of the passenger who does not check in but completes seat selection is computed based on the seat row number of the passenger who does not check in but completes seat selection, the weight of the passenger who does not check in but completes seat selection and the center of gravity index of a selected seat row of the passenger who does not check in but completes seat selection.

One embodiment of this application, the passenger who completes seat selection further includes a stretcher passenger.

After the center of gravity influence index of the passenger who does not check in but completes seat selection is computed, the method further includes the following steps:
a weight of the stretcher passenger is obtained from a departure system, the weight of the stretcher passenger is allocated to a plurality of seat rows indicated by the seat row number of the stretcher passenger according to a preset weight allocation rule, and a weight of each of the seat rows selected by the stretcher passenger is obtained, where the preset weight allocation rule is as follows: the weight of the stretcher passenger is evenly allocated to the plurality of seat rows so as to ensure that the weight obtained by each of the seat rows is consistent, and a remaining weight is sequentially allocated to each of the seat rows in an order from smaller seat row numbers to larger seat row numbers; and
the center of gravity influence index of the stretcher passenger is computed based on the seat row number of the stretcher passenger, the weight of each of the seat rows selected by the stretcher passenger and the center of gravity index of a seat row selected by the stretcher passenger.

One embodiment of this application, the passenger who completes seat selection further includes an extra seat occupation article.

After the center of gravity influence index of the stretcher passenger is computed, the method further includes the following steps:
a weight of the extra seat occupation article is obtained from the departure system, and the center of gravity influence index of the extra seat occupation article is computed based on the seat row number of the extra seat occupation article, the weight of the extra seat occupation article and the center of gravity index of a seat row selected by the extra seat occupation article.

One embodiment of this application, the passenger who completes seat selection further includes a flight crew jump seat passenger.

After the center of gravity influence index of the extra seat occupation article is computed, the method further includes the following steps:
a weight of the flight crew jump seat passenger and the center of gravity influence index of a seat selected by the flight crew jump seat passenger are obtained from the departure system, and the center of gravity influence index of the flight crew jump seat passenger is computed based on the weight of the flight crew jump seat passenger and the center of gravity influence index of the seat selected by the flight crew jump seat passenger.

One embodiment of this application, the passenger who completes seat selection further includes hand baggage.

After the center of gravity influence index of the flight crew jump seat passenger is computed, the method further includes the following steps:
a weight of the hand baggage is obtained from the departure system, and the center of gravity influence index of the hand baggage is computed based on the seat row number of the hand baggage, the weight of the hand baggage and the center of gravity index of a seat row selected by the hand baggage.

One embodiment of this application, the method further includes the following step: the sum of the center of gravity influence index of the checked-in passenger, the center of gravity influence index of the passenger who does not check in but completes seat selection, the center of gravity influence index of the stretcher passenger, the center of gravity influence index of the extra seat occupation article, the center of gravity influence index of the flight crew jump seat passenger and the center of gravity influence index of the hand baggage is identified as the center of gravity influence index of the passenger who completes seat selection.

One embodiment of this application, the steps that a seat is allocated to the passenger who does not complete seat selection, and a seat row number of the passenger who does not complete seat selection is obtained include the following steps:
the seat is allocated to the passenger who does not complete seat selection according to a preset passenger seat allocation rule, and the seat row number of the passenger who does not complete seat selection is obtained. The passenger seat allocation rule is as follows: for each of the seat rows, a plurality of priorities are preset for seats of the seat row, and a number of seats in each of the priorities is limited, such that the sum of the numbers of the seats in all the priorities equals a number of the seats of the seat row. A number of first seats included in the seat row is counted, and the number of the first seats of the seat row is obtained. In a case that the number of the first seats is smaller than that of the seats of the seat row, a seat row number and a priority of second seats included in the seat row are obtained. For the second seats included in each of the seat rows, in an order from higher priorities to lower priorities and an order from smaller seat row numbers to larger seat row numbers, each of the second seats is identified as a positive-sequence seat and allocated to each passenger who does not complete seat selection. In the order from higher priorities to lower priorities and an order from larger seat row numbers to smaller seat row numbers, each of the second seats is identified as a negative-sequence seat and allocated to each passenger who does not complete seat selection. The first seats represent seats selected by the passengers. The second seats represent seats not selected by the passengers.

An apparatus for estimating a center of gravity of flight passengers includes: an information obtainment unit configured to obtain passenger data, cabin layout information and a passenger weight table of a to-be-measured flight, where the passenger data includes passenger attribute and seat attribute of each of the passengers; type of each of the passengers includes a passenger who completes seat selection and a passenger who does not complete seat selection; the seat attribute includes a seat row number and a seat number of the passenger who completes seat selection; the seat row number indicates a seat row selected by the passenger; the cabin layout information includes a center of gravity index of each of the seat rows; and the passenger weight table includes a weight of a passenger corresponding to each of the passenger attributes; and types of the passenger attribute comprise an adult passenger, a male passenger, a female passenger, a child passenger, and an infant passenger;
a first determination unit configured to based on the passenger weight table and the passenger attribute of the passenger who completes seat selection, determine a weight of the passenger who completes seat selection, and based on the seat row number, the weight and the center of gravity index of a selected seat row of the passenger who completes seat selection, compute a center of gravity influence index of the passenger who completes seat selection;
a seat allocation unit configured to allocate a seat to the passenger who does not complete seat selection through combination of a positive-sequence allocation manner and a negative-sequence allocation manner, based on a preset seat priority and a current number of remaining seats in each priority, and obtain a seat row number of the passenger who does not complete seat selection;
a second determination unit configured to based on the passenger weight table and the passenger attribute of the passenger who does not complete seat selection, determine a weight of the passenger who does not complete seat selection, and based on the seat row number, the weight and the center of gravity index of a selected seat row of the passenger who does not complete seat selection, compute a center of gravity influence index of the passenger who does not complete seat selection; and
a center of gravity computation unit configured to compute a center of gravity of the passengers of the to-be-measured flight based on the center of gravity influence index of the passenger who completes seat selection and the center of gravity influence index of the passenger who does not complete seat selection.

According to the technical solution provided by the present disclosure, the passenger data, the cabin layout information and the passenger weight table of the to-be-measured flight are obtained. The weight of the passenger who completes seat selection is determined based on the passenger weight table and the passenger attribute of the passenger who completes seat selection. The center of gravity influence index of the passenger who completes seat selection is computed based on the seat row number, the weight and the center of gravity index of the selected seat row of the passenger who completes seat selection. The seat is allocated to the passenger who does not complete seat selection, and the seat row number of the passenger who does not complete seat selection is obtained. The weight of the passenger who does not complete seat selection is determined based on the passenger weight table and the passenger attribute of the passenger who does not complete seat selection. The center of gravity influence index of the passenger who does not complete seat selection is computed based on the seat row number, the weight and the center of gravity index of the selected seat row of the passenger who does not complete seat selection. The center of gravity of the passengers of the to-be-measured flight is computed based on the center of gravity influence index of the passenger who completes seat selection and the center of gravity influence index of the passenger who does not complete seat selection.

### BRIEF DESCRIPTION OF THE DRAWINGS

In order to more clearly illustrate technical solutions in examples of the present disclosure or in the prior art, the accompanying drawings required for the description of the examples or the prior art will be briefly introduced below. Obviously, the accompanying drawings in the following description are only some examples of the present disclosure, and those of ordinary skill in the art would also be able to derive other drawings from these drawings without making creative efforts.

FIG. 1A is a schematic flow diagram of a method for estimating a center of gravity of flight passengers according to an example of the present disclosure;

FIG. 1B is a schematic flow diagram of a method for estimating a center of gravity of flight passengers according to an example of the present disclosure;

FIG. 1C is a schematic allocation diagram of passenger seats according to an example of the present disclosure;

FIG. 2 is a schematic flow diagram of another method for estimating a center of gravity of flight passengers according to an example of the present disclosure; and

FIG. 3 is a schematic framework diagram of an apparatus for estimating a center of gravity of flight passengers according to an example of the present disclosure.

### DETAILED DESCRIPTION OF THE EMBODIMENTS

Technical solutions of examples of the present disclosure will be clearly and completely described below in conjunction with the accompanying drawings of the examples of the present disclosure. Obviously, the examples described are merely some examples rather than all examples of the present disclosure. Based on the examples of the present disclosure, all other examples obtained by those of ordinary skill in the art without making creative efforts fall within the protection scope of the present disclosure.

The terms “include” and “comprise” used herein and their variations are open-ended, that is, “include but not limited to” and “comprise but not limited to”. The term “based on” indicates “at least partly based on”. The term “one example” indicates “at least one example”. The term “another example” indicates “at least one another example”. The term “some examples” indicates “at least some examples”. Related definitions of other terms will be given in the following description. It should be noted that concepts such as “first” and “second” mentioned in the present disclosure are only used to distinguish different apparatuses, modules or units, and are not used to limit an order or interdependence of functions executed by the apparatuses, modules or units.

It should be noted that modifications with “a”, “an” and “a plurality of” mentioned in the present disclosure are schematic rather than limitative, and should be understood by those skilled in the art as “one or more” unless otherwise definitely indicated in the context.

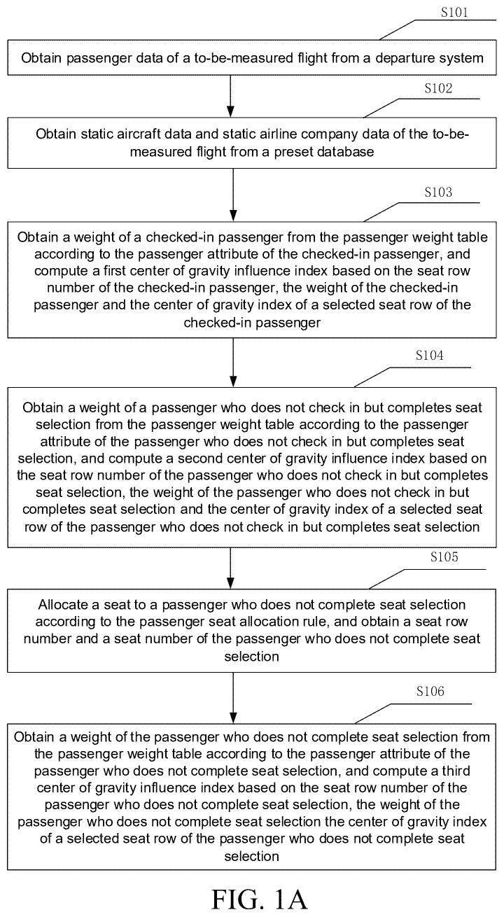

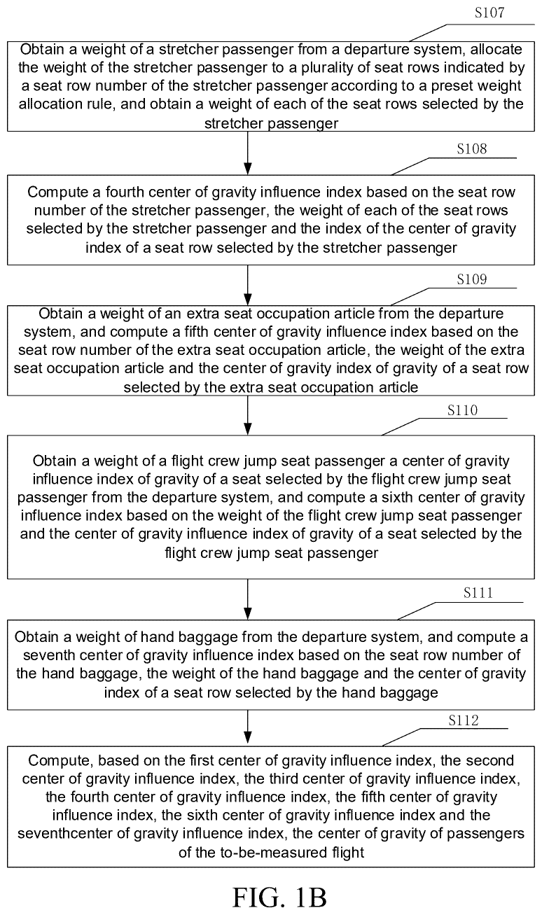

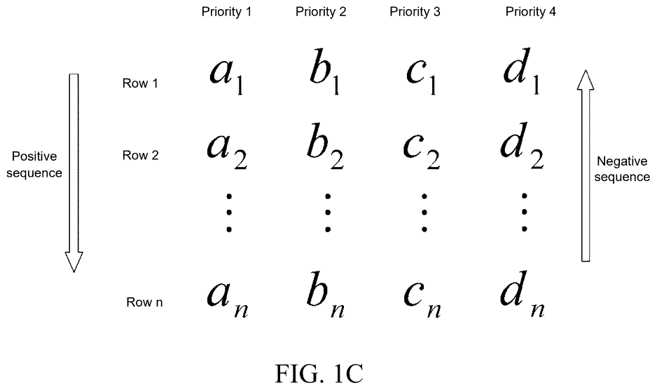

FIGS. 1A and 1B show schematic flow diagrams of a method for estimating a center of gravity of flight passengers according to an example of the present disclosure. The method includes the following steps:

S101: passenger data of a to-be-measured flight is obtained from a departure system.

The passenger data includes passenger attribute and seat attribute of each of the passengers. Type of each of the passengers includes a passenger who completes seat selection and a passenger who does not complete seat selection. The passengers who complete seat selection include a checked-in passenger, a passenger who does not check in but completes seat selection, a stretcher passenger, an extra seat occupation article, a jump seat passenger (commonly known as a flight crew jump seat passenger), and hand baggage. The seat attribute includes a seat row number and a seat number of the passenger who completes seat selection.

In the example of the present disclosure, the stretcher passenger represents a passenger who is incapable of moving and needs to arrange a plurality of seats. The extra seat occupation article represents valuables carried by the passenger, and the valuables need to be seated separately. The flight crew jump seat passenger represents a passenger who purchases a preset flight crew jump seat. The hand baggage represents baggage carried by the passenger, and a storage position of the baggage is located above the seat of the passenger.

Types of the passenger attribute include an adult passenger, a male passenger, a female passenger, a child passenger, and an infant passenger. Generally, the seat row number indicates a seat row selected by the passenger, and the seat number indicates a seat selected by the passenger. The seat row is a pre-configured seat combination in a flight. The flight may be pre-configured with a plurality of seat rows, and each of the seat rows includes a plurality of seats.

The checked-in passenger, the passenger who does not check in but completes seat selection, the stretcher passenger, the extra seat occupation article, the flight crew jump seat passenger and the hand baggage all select seats. That is, the seat row number and the seat number of the passenger who completes seat selection are known. Accordingly, the passenger who does not complete seat selection does not complete seat selection. Thus, a seat row number and a seat number of the passenger who does not complete seat selection are unknown.

Generally, a departure system may be searched for the passenger data of the to-be-measured flight based on an airline company, a flight number and a departure date. Before the to-be-measured flight is closed, reference for computing a center of gravity influence index of the passengers of the to-be-measured flight is obtained by collecting the passenger data.

S102: static aircraft data and static airline company data of the to-be-measured flight are obtained from a preset database.

The preset database includes static airline company data, static fleet data, static terminal data and static aircraft data of a plurality of flights.

It should be noted that the static aircraft data includes cabin layout information and a passenger seat allocation rule.

The cabin layout information includes a center of gravity index of each of the seat rows.

The passenger seat allocation rule is as follows: for each of the seat rows, a plurality of priorities are preset for seats of the seat row, and a number of seats in each of the priorities is limited, such that the sum of the numbers of the seats in all the priorities equals a number of the seats of the seat row. A number of first seats included in the seat row is counted, and the number of the first seats of the seat row is obtained. In a case that the number of the first seats is smaller than that of the seats of the seat row, a seat row number and a priority of second seats included in the seat row are obtained. For the second seats included in each of the seat rows, in an order from higher priorities to lower priorities and an order from smaller seat row numbers to larger seat row numbers, each of the second seats is identified as a positive-sequence seat and allocated to each passenger who does not complete seat selection. In the order from higher priorities to lower priorities and the order from smaller seat row numbers to larger seat row numbers, each of the second seats is identified as a negative-sequence seat and allocated to each passenger who does not complete seat selection.

It should be noted that the first seats represent seats selected by the passengers, and the second seats represent seats not selected by the passengers. Generally, a seat row having a smaller seat row number is generally before a seat row having a larger seat row number.

In other words, the passenger seat allocation rule may be specifically understood as follows: 4 priorities are preset for each row of seats, each of the priorities sets a number of seats, and the sum of the numbers of the seats in the 4 priorities equals a total number of seats in the row. In a case of allocating remaining seats, whether the sum of the checked-in passengers and the passengers who do not check in and complete seat selection in the seat row is smaller than the number of the seats in the row is determined first. If yes, allocation is further conducted in a first priority, and when the passenger who does not complete seat selection is allocated, the remaining seats of the checked-in passenger and the passenger who does not check in but completes seat selection need to be obtained first. Then, according to positive-sequence allocation, that is, allocation from front row seats to rear row seats in the first priority, if a number of seats in the first priority exceeds a number of to-be-allocated passengers (that is, a number of passengers who do not complete seat selection), remaining seats in each row of the first priority are directly allocated sequentially. If a number of seats in the first priority is smaller than a number of to-be-allocated passengers, and after allocation from a front row to a rear row in the first priority, allocation may continue from a front row to a rear row in a second priority. The rest can be done in the same manner until seats are allocated to all the passengers who do not complete seat selection. Then, according to negative-sequence allocation, that is, still starting from the first priority, allocation is conducted from a rear row to a front row, and the rest is similar to the positive-sequence allocation until all the passengers who do not complete seat selection complete seat allocation.

In the example of the present disclosure, the positive-sequence allocation manner is specifically as follows: in the order from higher priorities to lower priorities and the order from smaller seat row numbers to larger seat row numbers, each of the second seats is allocated to each passenger who does not complete seat selection. The negative-sequence allocation manner is specifically as follows: in the order from higher priorities to lower priorities and the order from larger seat row numbers to smaller seat row numbers, each of the second seats is allocated to each passenger who does not complete seat selection.

Specifically, with a seat allocation scene shown in FIG. 1C as an instance, a, b, c and d represent vacant seats in 4 priorities respectively, and subscripts 1 to n represent a corresponding nth row of seats. aₙ denotes a vacant seat of the nth row of seats in the first priority, bₙ denotes a vacant seat of the nth row of seats in the second priority, cₙ denotes a vacant seat of an nth row of seats in a third priority, and dₙ denotes a vacant seat of an nth row of seats in a fourth priority. The sum of aₙ, bₙ, cₙ and dₙ does not exceed a number of vacant seats in the nth row. The positive-sequence allocation starts from the first priority and starts from a first row to the nth row. If passengers remain after the vacant seats in the first priority are allocated, the allocation starts from the second priority and starts from the first row to the nth row. The rest can be done in the same manner. A negative sequence starts from the first priority, and allocation starts from a first row to an nth row. If a passenger who does not complete seat selection is still to be allocated after allocation in the first priority, allocation starts from the second priority and still starts from the nth row to the first row. The rest can be done in the same manner.

The static airline company data includes the passenger weight table. The passenger weight table includes a weight of a passenger corresponding to each of the passenger attributes, and specifically, includes a weight w^{adult} of the adult passenger, a weight w^{male} of the male passenger, a weight w^{female} of the female passenger, a weight w^{child} of the child passenger, and a weight w^{infant} of the infant passenger. The passenger weight table is obtained by weighing actual passengers regularly by airline companies and shows weights of adults, children and infants regularly updated according to international flights, domestic flights and different routes. Certainly, the weights of the adults may be divided into weights of the male and weights of the female.

Specifically, specific manifestations of the passenger weight table may be seen in Table 1.

TABLE 1

| Passenger attribute | Male | Female | Child | Infant |
|---|---|---|---|---|
| Weight (KG) | 73 | 73 | 38 | 10 |

The contents shown in Table 1 above are merely for illustration.

Specifically, it is assumed that reference may be made to Table 2 for the 4 priorities mentioned in the passenger seat allocation rule, the number of seats defined by each of the priorities, and the center of gravity index of each of the seat rows.

TABLE 2

| Seat row | Number of seats in each | | | | |
|---|---|---|---|---|---|
| number | priority | | | | Center of gravity index |
| 11 | 3 | 0 | 0 | 3 | −0.007139 |
| 12 | 3 | 0 | 0 | 3 | −0.006367 |
| 13 | 3 | 0 | 0 | 3 | −0.005605 |
| 14 | 3 | 0 | 0 | 3 | −0.004843 |
| 15 | 3 | 0 | 0 | 3 | −0.003319 |
| 16 | 3 | 0 | 0 | 3 | −0.002557 |
| 17 | 3 | 0 | 0 | 3 | −0.001668 |
| 18 | 3 | 0 | 0 | 3 | −0.000779 |

The contents shown in Table 2 above are merely for illustration.

S103: a weight of the checked-in passenger is obtained from the passenger weight table according to the passenger attribute of the checked-in passenger, and a first center of gravity influence index is computed based on the seat row number of the checked-in passenger, the weight of the checked-in passenger and the center of gravity index of a selected seat row of the checked-in passenger.

Reference may be made to formulas (1), (2) and (3), where a specific implementation process of the first center of gravity influence index is computed based on the seat row number of the checked-in passenger, the weight of the checked-in passenger and the center of gravity index of a selected seat row of the checked-in passenger. In the example of the present disclosure, the first center of gravity influence index may be regarded as a center of gravity influence index of the checked-in passenger.

$${w}_{j}^{ch} = n \cdot {w}^{adult} + m \cdot {w}^{child} + k \cdot {w}^{infant} \qquad ( 1 )$$

$${w}_{j}^{ch} = t \cdot {w}^{female} + h \cdot {w}^{male} + m \cdot {w}^{child} + k \cdot {w}^{infant} \qquad ( 2 )$$

$${CG}_{ch} = {{\sum }_{j = 1}}^{n} {w}_{j}^{ch} \cdot {index}_{j} \qquad ( 3 )$$

In the formulas (1) and (2),

$${w}_{j}^{ch}$$

denotes a total weight of check-in passengers in a jth row, n denotes a number of adult passengers of the checked-in passengers in the jth row, m denotes a number of child passengers of the checked-in passengers in the jth row, k denotes a number of infant passengers of the checked-in passengers in the jth row, t denotes a number of female passengers of the checked-in passengers in the jth row, and h denotes a number of male passengers of the checked-in passengers in the jth row. w^{adult} denotes a weight of a checked-in passenger whose passenger attribute is an adult passenger, w^{male} denotes a weight of a checked-in passenger whose passenger attribute is a male passenger, w^{female} denotes a weight of a checked-in passenger whose passenger attribute is a female passenger, w^{child} denotes a weight of a checked-in passenger whose passenger attribute is a child passenger, and w^{infant} denotes a weight of a checked-in passenger whose passenger attribute is an infant passenger.

In the formula (3), CG_{ch} denotes the first center of gravity influence index, n denotes a number of checked-in passengers, and indexⱼ denotes a center of gravity index of a jth seat row.

Specifically, with the seat row number of the checked-in passenger and the center of gravity index of the selected seat row of the checked-in passenger shown in Table 3 as an instance:

| Seat | Checked- | Checked- | Checked- | Checked- | Center of |
|---|---|---|---|---|---|
| row | in male | in female | in child | in infant | gravity |
| number | passenger | passenger | passenger | passenger | index |
| 11 | 2 | 2 | 1 | 0 | −0.007139 |
| 12 | 1 | 1 | 0 | 1 | −0.006367 |
| 13 | 1 | 0 | 0 | 0 | −0.005605 |

With reference to the passenger weight table shown in Table 1, it may be known that a total weight of checked-in passengers in a 11th row is 73×2+73×2+38×1=330 KG; a total weight of checked-in passengers in a 12th row is 73×1+73×1+10×1=156 KG; and a total weight of checked-in passengers in a 12th row is 73×1=73 KG. According to the formula (3), the first center of gravity influence index of each of the seat rows shown in Table 3 is further computed as:

-0.007139×330+(−0.006367)×156+(−0.005605)×73=−3.758287.

It should be noted that the specific implementation process is merely for illustration.

S104: a weight of the passenger who does not check in but completes seat selection is obtained from the passenger weight table according to the passenger attribute of the passenger who does not check in but completes seat selection, and a second center of gravity influence index is computed based on the seat row number of the passenger who does not check in but completes seat selection, the weight of the passenger who does not check in but completes seat selection and the center of gravity index of a selected seat row of the passenger who does not check in but completes seat selection.

Reference may be made to formulas (4), (5) and (6), where a specific implementation process of the second center of gravity influence index is computed based on the seat row number of the passenger who does not check in but completes seat selection, the weight of the passenger who does not check in but completes seat selection and the center of gravity index of a selected seat row of the passenger who does not check in but completes seat selection. In the example of the present disclosure, the second center of gravity influence index may be regarded as a center of gravity influence index of the passenger who does not check in but completes seat selection.

$${w}_{ave}^{noch} = ( f \cdot {w}^{femaile} + m \cdot {w}^{male} + c \cdot {w}^{child} + i \cdot {w}^{infant} ) / {N}^{noch} \qquad ( 4 )$$

$${N}^{noch} = f + m + c \qquad ( 5 )$$

$${CG}_{noch} = {{\sum }_{j = 1}}^{n} {N}_{j}^{noch} \cdot {w}_{ave}^{noch} \cdot {index}_{j} \qquad ( 6 )$$

In the formulas (4) and (5),

$${w}_{ave}^{noch}$$

denotes a mean weight of the passenger who does not check in but completes seat selection, f denotes a number of male passengers who do not check in and complete seat selection, m denotes a number of female passengers who do not check in and complete seat selection, c denotes a number of child passengers who do not check in and complete seat selection, and i denotes a number of infant passengers who do not check in and complete seat selection. w^{adult} denotes a weight of a passenger who does not check in but completes seat selection and has a passenger attribute of an adult passenger, w^{male} denotes a weight of a passenger who does not check in but completes seat selection and has a passenger attribute of a male passenger, w^{female} denotes a weight of a passenger who does not check in but completes seat selection and has a passenger attribute of a female passenger, w^{child} denotes a weight of a passenger who does not check in but completes seat selection and has a passenger attribute of a child passenger, w^{infant} denotes a weight of a passenger who does not check in but completes seat selection and has a passenger attribute of an infant passenger, and N^{noch} denotes a number of passengers who do not check in and complete seat selection.

In the formula (6), CG_{noch} denotes the second center of gravity influence index, n denotes the number of the passengers who do not check in and complete seat selection,

$${N}_{j}^{noch}$$

denotes a number of passengers who do not check in and complete seat selection in the jth row, and indexⱼ denotes a center of gravity index of the jth seat row.

Specifically, with the seat row number of the passenger who does not check in but completes seat selection and the center of gravity index of the selected seat row of the passenger who does not check in but completes seat selection shown in Table 4 as an instance:

TABLE 4

| | Male | Female | Child | Infant | |
|---|---|---|---|---|---|
| | passenger | passenger | passenger | passenger | |
| | who does | who does | who does | who does | |
| | not check in | not check in | not check in | not check in | Center of |
| Seat row | but completes | but completes | but completes | but completes | gravity |
| number | seat selection | seat selection | seat selection | seat selection | index |
| 12 | 1 | 1 | 0 | 1 | −0.006367 |
| 13 | 0 | 1 | 0 | 0 | −0.005605 |
| 14 | 2 | 1 | 0 | 0 | −0.004843 |

With reference to the passenger weight table shown in Table 1, it may be known that a mean weight of passengers who do not check in and complete seat selection in 12th, 13th and 14th rows may be:

(73×(1+2)+73×(1+1+1)+10×1)/(1+2+1+1+1)=74.66666667 KG.

According to the formula (6), a center of gravity influence index of a 12th seat row is −0.006367×(1+1+1)×74.66666667=−4.278624; a center of gravity influence index of a 13th seat row is −0.005605×1×74.66666667=−0.41850667; and a center of gravity influence index of a 14th seat row is −0.004834×(2+1)×74.66666667=−1.084832.

In view of that, the second center of gravity influence index of each of the seat rows shown in Table 4 is:

-4.278624+(−0.41850667)+(−1.084832)=−5.781963.

It should be noted that the specific implementation process is merely for illustration.

S105: a seat is allocated to the passenger who does not complete seat selection according to the passenger seat allocation rule, and a seat row number and a seat number of the passenger who does not complete seat selection are obtained.

The seat is allocated to the passenger who does not complete seat selection according to the passenger seat allocation rule. After the seat row number and the seat number of the passenger who does not complete seat selection are obtained, the seat row number and the seat number of the passenger who does not complete seat selection become known. That is, a seat row and a seat selected by the passenger who does not complete seat selection may be determined.

Specifically, numbers of passengers who do not complete seat selection and have different passenger attributes are as shown in Table 5.

TABLE 5

| | Male | Female | Child | Infant |
|---|---|---|---|---|
| Passenger | passenger | passenger | passenger | passenger |
| who does not | who does not | who does not | who does not | who does not |
| complete seat | complete seat | complete seat | complete seat | complete seat |
| selection | selection | selection | selection | selection |
| Number | 10 | 8 | 2 | 0 |

With the passengers who do not complete seat selection shown in Table 5 as an instance, the seat is allocated to the passenger who does not complete seat selection according to the passenger seat allocation rule, and the seat row number of the passenger who does not complete seat selection is obtained, as shown in Table 6.

TABLE 6

| | Number of remaining seats in | | | | Center of |
|---|---|---|---|---|---|
| Seat | each priority (That is, a | | | | gravity |
| row | number of second seats) | | | | index |
| 11 | 0 | 0 | 0 | 1 | −0.007139 |
| 12 | 0 | 0 | 0 | 2 | −0.006367 |
| 13 | 1 | 0 | 0 | 3 | −0.005605 |
| 14 | 0 | 0 | 0 | 3 | −0.004843 |
| 15 | 3 | 0 | 0 | 3 | −0.003319 |
| 16 | 3 | 0 | 0 | 3 | −0.002557 |
| 17 | 3 | 0 | 0 | 3 | −0.001668 |
| 18 | 3 | 0 | 0 | 3 | −0.000779 |

It should be noted that the contents shown in Table 5 and Table 6 are merely for illustration.

S106: a weight of the passenger who does not complete seat selection is obtained from the passenger weight table according to the passenger attribute of the passenger who does not complete seat selection, and a third center of gravity influence index is computed based on the seat row number of the passenger who does not complete seat selection, the weight of the passenger who does not complete seat selection and the center of gravity index of a selected seat row of the passenger who does not complete seat selection.

Reference may be made to formulas (7), (8), (9), (10) and (11), where a specific implementation process of the third center of gravity influence index is computed based on the seat row number of the passenger who does not complete seat selection, the weight of the passenger who does not complete seat selection and the center of gravity index of a selected seat row of the passenger who does not complete seat selection. In the example of the present disclosure, the third center of gravity influence index may be regarded as a center of gravity influence index of the passenger who does not complete seat selection.

$${w}_{ave}^{noseat} = ( e \cdot {w}^{female} + r \cdot {w}^{male} + y \cdot {w}^{child} + p \cdot {w}^{noseat} ) / {N}^{noseat} \qquad ( 7 )$$

$${N}^{noseat} = e + r + y \qquad ( 8 )$$

$${CG}_{noseat}^{pos} = {\sum }_{j = 1}^{n} {N}_{j}^{pos} \cdot {w}_{ave}^{noseat} \cdot {index}_{j} \qquad ( 9 )$$

$${CG}_{noseat}^{inv} = {\sum }_{j = 1}^{n} {N}_{j}^{inv} \cdot {w}_{ave}^{noseat} \cdot {index}_{j} \qquad ( 10 )$$

$${CG}_{noseat} = ( {CG}_{noseat}^{pos} + {CG}_{noseat}^{inv} ) / 2 \qquad ( 11 )$$

In the formulas (7) and (8),

$${w}_{ave}^{noseat}$$

denotes a mean weight of the passenger who does not complete seat selection, e denotes a number of male passengers who do not complete seat selection, r denotes a number of female passengers who do not complete seat selection, y denotes a number of child passengers who do not complete seat selection, and p denotes a number of infant passengers who do not complete seat selection. w^{adult} denotes a weight of a passenger who does not complete seat selection and has a passenger attribute of an adult passenger, w^{male} denotes a weight of a passenger who does not complete seat selection and has a passenger attribute of a male passenger, w^{female} denotes a weight of a passenger who does not complete seat selection and has a passenger attribute of a female passenger, w^{child} denotes a weight of a passenger who does not complete seat selection and has a passenger attribute of a child passenger, w^{infant} denotes a weight of a passenger who does not complete seat selection and has a passenger attribute of an infant passenger, and N^{noseat} denotes a number of passengers who do not complete seat selection.

In the above formulas (9), (10) and (11),

$${CG}_{noseat}^{pos}$$

denotes a positive-sequence center of gravity influence index (that is, a center of gravity influence index computed after a positive-sequence seat is allocated to each passenger who does not complete seat selection according to the positive-sequence allocation manner mentioned above).

$${CG}_{noseat}^{inv}$$

denotes a negative-sequence center of gravity influence index (that is, a center of gravity influence index computed after a negative-sequence seat is allocated to each passenger who does not complete seat selection according to the negative-sequence allocation manner mentioned above). CGₙₒₛₑₐₜ denotes the third center of gravity influence index.

$${N}_{j}^{pos}$$

denotes a number of passengers who do not complete seat selection, allocated with seats, in the jth row in the positive-sequence allocation manner.

$${N}_{j}^{inv}$$

denotes a number of passengers who do not complete seat selection, allocated with seats, in the jth row in the negative-sequence allocation manner. indexⱼ denotes the center of gravity index of the jth seat row.

It should be noted that sometimes there may be a situation that seats are oversold on a flight. For instance, aircraft layout of a flight is F8Y120, but an actual booking passenger is F5Y122. Thus, it is necessary to upgrade two oversold passengers from cabin Y to cabin F, and the passenger seat allocation rule is also used for seat allocation of upgraded passengers, and is also applied to computation. In other words, the upgraded passengers are regarded as passengers who do not complete seat selection for seat allocation.

Specifically, with the passengers who do not complete seat selection shown in Table 5 as an instance, it is assumed that 20 passengers who do not complete seat selection need to undergo seat allocation.

Firstly, according to the positive-sequence allocation, starting from the first priority, allocation is conducted from the 11th row to the 18th row, with 1+3×4=13 seats remaining in all rows of the first priority, 8 passengers who do not complete seat selection still remain after the remaining seats in the first priority are allocated, and the priority is increased sequentially. Since the 2nd and 3rd priorities have no vacant seats, seats in the 4th priority are allocated, and allocation may be conducted according to 1 in the 11th row, 2 in the 12th row, 3 in the 13th row and 2 in the 14th row, such that all passengers who do not complete seat selection complete seat allocation. Seat allocation results obtained by the positive-sequence allocation method may be shown in Table 7. According to the passenger weight table shown in Table 1, the seat allocation results shown in Table 7 and the formula (7), weight allocation results obtained may be shown in Table 8.

TABLE 7

| | Number of passengers | |
|---|---|---|
| | who do not complete seat | |
| Seat row number | selection | Center of gravity index |
| 11 | 1 | −0.007139 |
| 12 | 2 | −0.006367 |
| 13 | 4 | −0.005605 |
| 14 | 2 | −0.004843 |
| 15 | 3 | −0.003319 |
| 16 | 3 | −0.002557 |
| 17 | 3 | −0.001668 |
| 18 | 3 | −0.000779 |

TABLE 8

| | Total weight of passengers | |
|---|---|---|
| | who do not complete seat | |
| Seat row number | selection (KG) | Center of gravity index |
| 11 | 69.5 | −0.007139 |
| 12 | 139 | −0.006367 |
| 13 | 278 | −0.005605 |
| 14 | 139 | −0.004843 |
| 15 | 208.5 | −0.003319 |
| 16 | 208.5 | −0.002557 |
| 17 | 208.5 | −0.001668 |
| 18 | 208.5 | −0.000779 |

According to a number of passengers who do not complete seat selection in each of the seat rows shown in Table 7, a total weight of passengers who do not complete seat selection in each of the seat rows shown in Table 8 and the formula (9), a positive-sequence center of gravity influence index of each of the seat rows shown in Table 6 is computed as:

69.5×(−0.007139)+139×(−0.004834)+ . . . +208.5×0.000779=−5.347886.

Then, according to the negative-sequence allocation manner, starting from the first priority, allocation is conducted from the 18th row to the 11th row, with 1+3×4=13 seats remaining in all rows of the first priority, 8 passengers who do not complete seat selection still remain after the remaining seats in the first priority are allocated, and the priority is increased sequentially. Since the 2nd and 3rd priorities have no vacant seats, seats in the 4th priority are allocated, and allocation may be conducted according to 3 in the 18th row, 3 in the 17th row and 2 in the 16th row, such that all passengers who do not complete seat selection complete seat allocation. Seat allocation results obtained by the negative-sequence allocation manner may be shown in Table 9. According to the passenger weight table shown in Table 1, the seat allocation results shown in Table 9 and the formula (7), weight allocation results obtained may be shown in Table 10.

TABLE 9

| | Number of passengers | |
|---|---|---|
| | who do not complete | |
| Seat row number | seat selection | Center of gravity index |
| 11 | 0 | −0.007139 |
| 12 | 0 | −0.006367 |
| 13 | 1 | −0.005605 |
| 14 | 0 | −0.004843 |
| 15 | 3 | −0.003319 |
| 16 | 5 | −0.002557 |
| 17 | 6 | −0.001668 |
| 18 | 6 | −0.000779 |

TABLE 10

| | Total weight of passengers | |
|---|---|---|
| Seat row | who do not complete | Center of gravity |
| number | seat selection (KG) | index |
| 11 | 0 | −0.007139 |
| 12 | 0 | −0.006367 |
| 13 | 69.5 | −0.005605 |
| 14 | 0 | −0.004843 |
| 15 | 208.5 | −0.003319 |
| 16 | 347.5 | −0.002557 |
| 17 | 417 | −0.001668 |
| 18 | 417 | −0.000779 |

According to a number of passengers who do not complete seat selection in each of the seat rows shown in Table 9, a total weight of passengers who do not complete seat selection in each of the seat rows shown in Table 10 and the formula (10), a negative-sequence center of gravity influence index of each of the seat rows shown in Table 6 is computed as:

69.5×(−0.005605)+208.5×(−0.003319)+ . . . +417×(−0.000779)=−2.9905155.

Finally, the positive-sequence center of gravity influence index and the negative-sequence center of gravity influence index of each of the seat rows shown in Table 6 are substituted into the formula (11), and the third center of gravity influence index of each of the seat rows shown in Table 6 is computed as:

((−5.347886)+(−2.9905155))/2=−4.169201.

It should be noted that the specific implementation process is merely for illustration.

S107: a weight of the stretcher passenger is obtained from a departure system, the weight of the stretcher passenger is allocated to a plurality of seat rows indicated by a seat row number of the stretcher passenger according to a preset weight allocation rule, and a weight of each of the seat rows selected by the stretcher passenger is obtained.

It is common knowledge in the aviation field that the stretcher passenger generally occupies a plurality of seat rows. In the example of the present disclosure, based on the seat row number of the stretcher passenger, a number of seat rows selected by the stretcher passenger may be determined.

It should be noted that the preset weight allocation rule may be as follows: the weight of the stretcher passenger is evenly allocated to the plurality of seat rows so as to ensure that the weight obtained by each of the seat rows is consistent, and a remaining weight is sequentially allocated to each of the seat rows in an order from smaller seat row numbers to larger seat row numbers.

S108: a fourth center of gravity influence index is computed based on the seat row number of the stretcher passenger, the weight of each of the seat rows selected by the stretcher passenger and the center of gravity index of a seat row selected by the stretcher passenger.

Reference may be made to a formula (12), where a specific implementation process of the fourth center of gravity influence index is computed based on the seat row number of the stretcher passenger, the weight of each of the seat rows selected by the stretcher passenger and the center of gravity index of a seat row selected by the stretcher passenger. In the example of the present disclosure, the fourth center of gravity influence index may be regarded as an center of gravity influence index of the stretcher passenger.

$${CG}_{str} = {\sum }_{i = 1}^{m} {\sum }_{j = 1}^{n} {w}_{ij}^{str} \cdot {index}_{j} \qquad ( 12 )$$

In the formula (12), CGₛₜᵣ denotes the fourth center of gravity influence index, m denotes a number of stretcher passengers, n denotes a number of seat rows selected by the stretcher passenger, w″

$${w}_{ij}^{str}$$

denotes a weight of the jth row selected by the stretcher passenger, and indexⱼ denotes a center of gravity index of the jth seat row.

Specifically, assuming that there are two stretcher passengers, seats occupied by the two stretcher passengers are shown in Table 11. A weight of a stretcher passenger 1 is 200 KG. The weight of the stretcher passenger 1 is evenly applied to 14-16 rows of seats, and 2 KG remains after 66 KG is allocated to each row of seats. In this case, 1 KG is added to the 14th row, 1 KG is added to the 15th row, and finally 67 KG, 67 KG and 66 KG are allocated from the 14th row to the 16th row.

TABLE 11

| Stretcher | Starting row | Ending row | |
|---|---|---|---|
| passenger | weight | weight | Weight (KG) |
| 1 | 14 | 16 | 200 |
| 2 | 14 | 16 | 150 |

In Table 11, a starting row is a seat row having a minimum seat row number in the plurality of seat rows selected by the stretcher passenger. An ending row is a seat row having a maximum seat row number in the plurality of seat rows selected by the stretcher passenger. Similarly, after a weight of stretcher passenger 2 is evenly applied, it is ensured that a weight of each of the seat rows is 150 KG. A weight of each of the seat rows selected by the stretcher passenger is shown in Table 12.

TABLE 12

| Seat row | Stretcher | Stretcher | Center of |
|---|---|---|---|
| number | passenger 1 | passenger 2 | gravity index |
| 14 | 67 | 50 | −0.004843 |
| 15 | 67 | 50 | −0.003319 |
| 16 | 66 | 50 | −0.002557 |

Finally, according to the weight and the center of gravity index of each of the seat rows selected by the stretcher passenger and the formula (12) shown in Table 12, the fourth center of gravity influence index of the two stretcher passengers is −1.251566.

It should be noted that the specific implementation process is merely for illustration.

S109: a weight of the extra seat occupation article is obtained from the departure system, and a fifth center of gravity influence index is computed based on the a seat row number of the extra seat occupation article, the weight of the extra seat occupation article and the center of gravity index of a seat row selected by the extra seat occupation article.

Reference may be made to a formula (13), where a specific implementation process of the fifth center of gravity influence index is computed based on the seat row number of the extra seat occupation article, the weight of the extra seat occupation article and the center of gravity index of a seat row selected by the extra seat occupation article. In the example of the present disclosure, the fifth center of gravity influence index may be regarded as a center of gravity influence index of the extra seat occupation article.

$${CG}_{extra} = {\sum }_{j = 1}^{n} {\sum }_{i = 0}^{m} {w}_{ji}^{extra} \cdot {index}_{j} \qquad ( 13 )$$

In the formula (13), CGₑₓₜᵣₐ denotes the fifth center of gravity influence index, n denotes a number of the seat rows of the to-be-measured flight, m denotes a number of extra seat occupation articles included by each of the seat rows,

$${w}_{ji}^{extra}$$

denotes a weight of an ith extra seat occupation article in the jth row, and indexⱼ denotes a center of gravity index of the jth seat row.

Specifically, assuming that weights and seat row numbers of two extra seat occupation articles are provided, as shown in Table 13, according to the formula (13), the fifth center of gravity influence index of the two extra seat occupation articles is computed as: 5×(−0.003319)+8×(−0.002557)=−0.037051.

TABLE 13

| | | Weight | Center of |
|---|---|---|---|
| | Seat row | (KG) | gravity index |
| Extra seat occupation | 15 | 5 | −0.003319 |
| article 1 | | | |
| Extra seat occupation | 16 | 8 | −0.002557 |
| article 2 | | | |

It should be noted that the contents shown in Table 13 are merely for illustration.

S110: a weight of the flight crew jump seat passenger and a center of gravity influence index of a seat selected by the flight crew jump seat passenger are obtained from the departure system, and a sixth center of gravity influence index is computed based on the weight of the flight crew jump seat passenger and the center of gravity influence index of a seat selected by the flight crew jump seat passenger.

Each seat (that is, a flight crew jump seat) selected by the flight crew jump seat passenger is separate, and the flight crew jump seat passenger has a separate weight. The seat selected by the flight crew jump seat passenger has a separate center of gravity influence index. Thus, the influence indexes of the center of gravity of the seats selected by all the flight crew jump seat passengers are added together, such that the sixth center of gravity influence index is obtained.

In the example of the present disclosure, reference may be made to a formula (14), where a specific implementation process of the sixth center of gravity influence index is computed based on the weight of the flight crew jump seat passenger and the center of gravity influence index of a seat selected by the flight crew jump seat passenger. In the example of the present disclosure, the sixth center of gravity influence index may be regarded as a center of gravity influence index of the flight crew jump seat passenger.

$${CG}_{jump} = {\sum }_{i = 1}^{m} {w}_{i}^{jump} \cdot {index}_{i}^{jump} \qquad ( 14 )$$

In the formula (14), CGⱼᵤₘₚ denotes the sixth center of gravity influence index, m denotes a number of flight crew jump seat passengers,

$${w}_{i}^{jump}$$

denotes a weight of an ith flight crew jump seat passenger, and

$${index}_{i}^{jump}$$

denotes a center of gravity influence index of a seat selected by an ith flight crew jump seat passenger.

Specifically, assuming that the weight of a flight crew jump seat passenger is 60 KG and the center of gravity influence index of a seat selected by the flight crew jump seat passenger is 0.004, the number of the flight crew jump seat passengers is 6, and according to the formula (14), the sixth center of gravity influence index of each flight crew jump seat passenger is computed as 6×0.004=0.24.

It should be noted that the specific implementation process is merely for illustration.

S111: a weight of the hand baggage is obtained from the departure system, and a seventh center of gravity influence index is computed based on the seat row number of the hand baggage, the weight of the hand baggage and the center of gravity index of a seat row selected by the hand baggage.

The hand baggage is separately weighed, and a weight of the hand baggage is input into the departure system. A seat row where the hand baggage is located is generally considered to be consistent with that of a passenger carrying the hand baggage.

In the example of the present disclosure, reference may be made to a formula (15), where a specific implementation process of the seventh center of gravity influence index is computed based on the seat row number of the hand baggage and the weight of the hand baggage. In the example of the present disclosure, the seventh center of gravity influence index may be regarded as a center of gravity influence index of the hand baggage.

$${CG}_{handBag} = {\sum }_{j = 1}^{n} {\sum }_{i = 1}^{m} {w}_{ji}^{handBag} \cdot {index}_{j} \qquad ( 15 )$$

In the formula (15), CG_{handBag} denotes the seventh center of gravity influence index, n denotes a number of the seat rows of the to-be-measured flight, m denotes a number of hand baggage,

$${w}_{ij}^{handBag}$$

denotes a weight of ith hand baggage in the jth row, and indexⱼ denotes a center of gravity index of the jth seat row.

Specifically, assuming that weights and seat row numbers of 3 pieces of hand baggage are shown in Table 14, according to the formula (15), the seventh center of gravity influence index of each piece of the hand baggage shown in Table 14 is computed as: 12×(−0.007139)+15×(−0.0006367)+18×(−0.005606)=−0.282063.

TABLE 14

| Hand | | Weight | Center of gravity |
|---|---|---|---|
| baggage | Seat row | (KG) | index |
| 1 | 11 | 12 | −0.007139 |
| 2 | 12 | 15 | −0.006367 |
| 3 | 13 | 18 | −0.005605 |

It should be noted that the contents shown in Table 14 are merely for illustration.

S112: based on the first center of gravity influence index, the second center of gravity influence index, the third center of gravity influence index, the fourth center of gravity influence index, the fifth center of gravity influence index, the sixth center of gravity influence index and the seventh center of gravity influence index, the center of gravity of the passengers of the to-be-measured flight is computed.

Reference may be made to a formula (16), where a specific implementation process of the center of gravity of the passengers of the to-be-measured flight is computed, based on the first center of gravity influence index, the second center of gravity influence index, the third center of gravity influence index, the fourth center of gravity influence index, the fifth center of gravity influence index, the sixth center of gravity influence index and the seventh center of gravity influence index.

CGₚₐₛₛ=CG_{ch}+CG_{much}+CG_{noSeat}+CGₙₜᵣ+CGₑₓₜᵣₐ+CGⱼᵤₘₚ+CG_{handBag} (16)

In the formula (16), CGₚₐₛₛ denotes the center of gravity of the passengers.

Based on the flows shown in S101-S112, the example can achieve beneficial effects in the three following aspects:

In an aspect of resource allocation of load management: in a traditional loading process, only a small amount of passenger check-in data is mastered at the beginning, and cargo loading needs to be estimated according to the limited data and prior experience. In addition, a cargo loading solution is made accordingly. The method not only relies too much on human experience, but also has a risk of inaccurate estimation. In the example, the center of gravity of the passengers is estimated in real time from a moment of loading, which not only reduces labor cost, but also improves estimation accuracy.

In an aspect of service requirements: although many seats of the passengers are unknown from loading work of a flight, the apparatus can start to estimate the center of gravity of the passengers. In this way, cargo loading can be guided more effectively, and the situation that when all the passengers need to finally adjust the center of gravity after check-in, the passengers further need to adjust the center of gravity by adjusting cargoes in a cargo hold can be avoided.

The example can greatly reduce a probability of adjusting the cargoes. Meanwhile, when the probability of adjusting the cargoes in the cargo hold is reduced, a probability of a flight delay is further reduced.

In an aspect of a computation rule: the core of the example is seat allocation for the passengers who do not complete seat selection. By setting the plurality of priorities, a mean value of the influence indexes of the center of gravity of the two allocation solutions is used as the third center of gravity influence index according to the positive-sequence allocation manner and the negative-sequence allocation manner, fully reflecting an idea of balancing in loading work. Meanwhile, for other types of passengers, an optimal matched computation method is also used. The passenger seat allocation rule used by the example is a breakthrough invention, and is effective and feasible by instances, which is in line with expectations.

In conclusion, in the example, the center of gravity influence index of the passenger who completes seat selection is determined based on the seat row number, the weight and the center of gravity index of the selected seat row of the passenger who completes seat selection; the seat is allocated to the passenger who does not complete seat selection, and the seat row number of the passenger who does not complete seat selection is obtained; the center of gravity influence index of the passenger who does not complete seat selection is determined based on the seat row number, the weight and the center of gravity index of a selected seat row of the passenger who does not complete seat selection; and the center of gravity of the passengers of the to-be-measured flight is determined based on respective influence indexes of the center of gravity of the passenger who completes seat selection and the passenger who does not complete seat selection. Obviously, reference is made to the seat row numbers, the weights and the indexes of the center of gravity of the selected seat rows of the passenger who completes seat selection and the passenger who does not complete seat selection. Compared with the prior art, the present disclosure can effectively and accurately compute the center of gravity of the passengers of the to-be-measured flight.

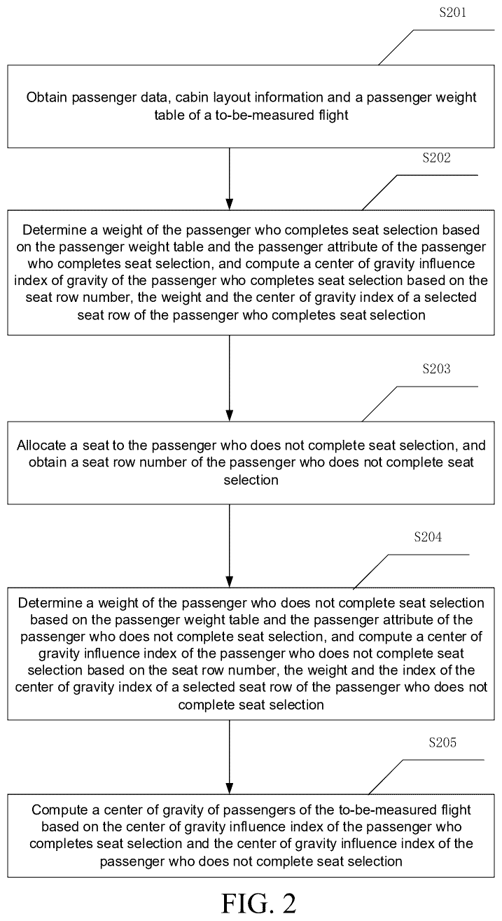

It should be noted that S101 mentioned in the example is an optional implementation of the method for estimating the center of gravity of flight passengers shown in the example of the present disclosure. In addition, S105 mentioned in the example is an optional implementation of the method for estimating the center of gravity of flight passengers shown in the example of the present disclosure. Thus, the flow mentioned in the example may be summarized as the method shown in FIG. 2.

FIG. 2 shows a schematic flow diagram of another method for estimating a center of gravity of flight passengers according to an example of the present disclosure. The method includes the following steps:

S201: passenger data, cabin layout information and a passenger weight table of a to-be-measured flight are obtained.

The passenger data includes passenger attribute and seat attribute of each of the passengers. Type of each of the passengers includes a passenger who completes seat selection and a passenger who does not complete seat selection. The seat attribute includes a seat row number of the passenger who completes seat selection. The seat row number indicates a seat row selected by the passenger. The cabin layout information includes a center of gravity index of each of the seat rows. The passenger weight table includes a weight of a passenger corresponding to each of the passenger attributes.

S202: a weight of the passenger who completes seat selection is determined based on the passenger weight table and the passenger attribute of the passenger who completes seat selection, and a center of gravity influence index of the passenger who completes seat selection is computed based on the seat row number, the weight and the center of gravity index of a selected seat row of the passenger who completes seat selection.

S203: a seat is allocated to the passenger who does not complete seat selection, and a seat row number of the passenger who does not complete seat selection is obtained.

S204: a weight of the passenger who does not complete seat selection is determined based on the passenger weight table and the passenger attribute of the passenger who does not complete seat selection, and a center of gravity influence index of the passenger who does not complete seat selection is computed based on the seat row number, the weight and the center of gravity index of a selected seat row of the passenger who does not complete seat selection.

S205: a center of gravity of the passengers of the to-be-measured flight is computed based on the center of gravity influence index of the passenger who completes seat selection and the center of gravity influence index of the passenger who does not complete seat selection.

In conclusion, according to the example, reference is made to the seat row numbers, the weights and the indexes of the center of gravity of a selected seat rows of the passenger who completes seat selection and the passenger who does not complete seat selection. Compared with the prior art, the present disclosure can effectively and accurately compute the center of gravity of the passengers of the to-be-measured flight.

It should be noted that, although all operations are depicted in a particular order, it should be understood that the operations are not required to be executed in the particular order shown or in a sequential order. In some cases, multitasking and parallel processing may be advantageous.

It should be understood that steps described in a method embodiment of the present disclosure may be executed in different orders and/or in parallel. Further, the method embodiment may include an additional step and/or omit a shown step, which do not limit the scope of the present disclosure.

In addition, computer program codes configured to execute the operations of the present disclosure may be written in one or more programming languages or their combinations, and the programming languages include, but are not limited to, object-oriented programming languages such as Java, Smalltalk, and C++, and further include conventional procedural programming languages including “C” languages or similar programming languages. The program codes may be completely executed on a computer of a user, partially executed on a computer of a user, executed as an independent software package, partially executed on a computer of a user and a remote computer separately, or completely executed on a remote computer or a server. In a case involving the remote computer, the remote computer may be connected to the computer of the user through any type of network, including a local area network (LAN) or a wide area network (WAN), or may be connected to an external computer (for instance, through the Internet provided by an Internet service provider).

Corresponding to the method for estimating the center of gravity of flight passengers according to the example of the present disclosure, an example of the present disclosure further provides an apparatus for estimating the center of gravity of flight passengers.

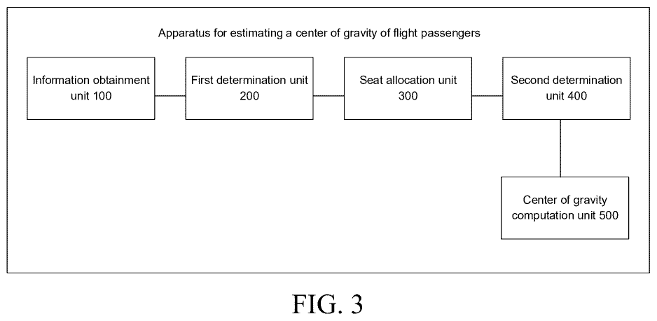

FIG. 3 shows a schematic framework diagram of an apparatus for estimating a center of gravity of flight passengers according to an example of the present disclosure. The apparatus includes:
an information obtainment unit 100 configured to obtain passenger data, cabin layout information and a passenger weight table of a to-be-measured flight, where the passenger data includes passenger attribute and seat attribute of each of the passengers; type of each of the passengers includes a passenger who completes seat selection and a passenger who does not complete seat selection; the seat attribute includes a seat row number and a seat number of the passenger who completes seat selection; the seat row number indicates a seat row selected by the passenger; the cabin layout information includes a center of gravity index of each of the seat rows; and the passenger weight table includes a weight of a passenger corresponding to each of the passenger attributes; and a first determination unit 200 configured to determine a weight of the passenger who completes seat selection based on the passenger weight table and the passenger attribute of the passenger who completes seat selection, and compute a center of gravity influence index of the passenger who completes seat selection based on the seat row number, the weight and the center of gravity index of a selected seat row of the passenger who completes seat selection.

One embodiment of this application, the passenger who completes seat selection includes a checked-in passenger.

The first determination unit 200 is specifically configured to: obtain a weight of the checked-in passenger from the passenger weight table according to the passenger attribute of the checked-in passenger, and compute a center of gravity influence index of the checked-in passenger based on the seat row number of the checked-in passenger, the weight of the checked-in passenger and the center of gravity index of a selected seat row of the checked-in passenger.

One embodiment of this application, the passenger who completes seat selection further includes a passenger who does not check in but completes seat selection.

The first determination unit 200 is further configured to: obtain a weight of the passenger who does not check in but completes seat selection from the passenger weight table according to the passenger attribute of the passenger who does not check in but completes seat selection, and compute a center of gravity influence index of the passenger who does not check in but completes seat selection based on the seat row number of the passenger who does not check in but completes seat selection, the weight of the passenger who does not check in but completes seat selection and the center of gravity index of a selected seat row of the passenger who does not check in but completes seat selection.

One embodiment of this application, the passenger who completes seat selection further includes a stretcher passenger.

The first determination unit 200 is further configured to: obtain a weight of the stretcher passenger from a departure system, allocate the weight of the stretcher passenger to a plurality of seat rows indicated by a seat row number of the stretcher passenger according to a preset weight allocation rule, and obtain a weight of each of the seat rows selected by the stretcher passenger. The preset weight allocation rule is as follows: the weight of the stretcher passenger is evenly allocated to the plurality of seat rows so as to ensure that the weight obtained by each of the seat rows is consistent, and a remaining weight is sequentially allocated to each of the seat rows in an order from smaller seat row numbers to larger seat row numbers; and a center of gravity influence index of the stretcher passenger is computed based on the seat row number of the stretcher passenger, the weight of each of the seat rows selected by the stretcher passenger and the center of gravity index of a seat row selected by the stretcher passenger.

One embodiment of this application, the passenger who completes seat selection further includes an extra seat occupation article.

The first determination unit 200 is further configured to: obtain a weight of the extra seat occupation article from the departure system, and compute a center of gravity influence index of the extra seat occupation article based on the seat row number of the extra seat occupation article, the weight of the extra seat occupation article and the center of gravity index of a seat row selected by the extra seat occupation article. One embodiment of this application, the passenger who completes seat selection further includes a flight crew jump seat passenger.

The first determination unit 200 is further configured to: obtain a weight of the flight crew jump seat passenger and a center of gravity influence index of a seat selected by the flight crew jump seat passenger from the departure system, and compute a center of gravity influence index of the flight crew jump seat passenger based on the weight of the flight crew jump seat passenger and the center of gravity influence index of a seat selected by the flight crew jump seat passenger.

One embodiment of this application, the passenger who completes seat selection further includes hand baggage.

The first determination unit 200 is further configured to: obtain a weight of the hand baggage from the departure system, and compute a center of gravity influence index of the hand baggage based on the seat row number of the hand baggage, the weight of the hand baggage and the center of gravity index of a seat row selected by the hand baggage.

One embodiment of this application, the first determination unit 200 is further configured to: identify the sum of the center of gravity influence index of the checked-in passenger, the center of gravity influence index of the passenger who does not check in but completes seat selection, the center of gravity influence index of the stretcher passenger, the center of gravity influence index of the extra seat occupation article, the center of gravity influence index of the flight crew jump seat passenger and the center of gravity influence index of the hand baggage as the center of gravity influence index of the passenger who completes seat selection.

A seat allocation unit 300 is configured to allocate a seat to the passenger who does not complete seat selection, and obtain a seat row number of the passenger who does not complete seat selection.

One embodiment of this application, the seat allocation unit 300 is specifically configured to: allocate the seat to the passenger who does not complete seat selection according to a preset passenger seat allocation rule, and obtain the seat row number of the passenger who does not complete seat selection. The passenger seat allocation rule is as follows: for each of the seat rows, a plurality of priorities are preset for seats of the seat row, and a number of seats in each of the priorities is limited, such that the sum of the numbers of the seats in all the priorities equals a number of the seats of the seat row. A number of first seats included in the seat row is counted, and the number of the first seats of the seat row is obtained. In a case that the number of the first seats is smaller than that of the seats of the seat row, a seat row number and a priority of second seats included in the seat row are obtained. For the second seats included in each of the seat rows, in an order from higher priorities to lower priorities and an order from smaller seat row numbers to larger seat row numbers, each of the second seats is identified as a positive-sequence seat and allocated to each passenger who does not complete seat selection. According to the order from higher priorities to lower priorities and an order from larger seat row numbers to smaller seat row numbers, each of the second seats is identified as a negative-sequence seat and allocated to each passenger who does not complete seat selection. The first seats represent seats selected by the passengers. The second seats represent seats not selected by the passengers.

A second determination unit 400 is configured to determine a weight of the passenger who does not complete seat selection based on the passenger weight table and the passenger attribute of the passenger who does not complete seat selection, and compute a center of gravity influence index of the passenger who does not complete seat selection based on the seat row number, the weight and the center of gravity index of a selected seat row of the passenger who does not complete seat selection.

A center of gravity computation unit 500 is configured to compute the center of gravity of the passengers of the to-be-measured flight based on the center of gravity influence index of the passenger who completes seat selection and the center of gravity influence index of the passenger who does not complete seat selection.

In conclusion, according to the example, reference is made to the seat row numbers, the weights and the indexes of the center of gravity of the selected seat rows of the passenger who completes seat selection and the passenger who does not complete seat selection. Compared with the prior art, the present disclosure can effectively and accurately compute the center of gravity of the passengers of the to-be-measured flight.

It should be noted that the units involved in the example of the present disclosure may be implemented by software or hardware. A name of the unit does not constitute limitation to the unit itself in some cases. For instance, a first obtainment unit may also be described as “a unit that obtains at least two Internet protocol addresses”.

In addition, the functions described in the above examples of the present disclosure may be executed at least partially by one or more hardware logic components. For instance, illustrative types of hardware logic components that may be used include: a field programmable gate array (FPGA), an application specific integrated circuit (ASIC), an application specific standard product (ASSP), a system on chip (SOC), a complex programmable logic device (CPLD), etc. in a non-restrictive way.

The present disclosure further provides a computer-readable storage medium. The computer-readable storage medium includes a stored program. The program executes the method for estimating the center of gravity of flight passengers according to the present disclosure.

The present disclosure further provides a device for estimating the center of gravity of flight passengers. The device includes: a processor, a memory, and a bus. The processor is connected to the memory through the bus. The memory is configured to store a program. The processor is configured to run a program. When the program runs, the method for estimating the center of gravity of flight passengers according to the present disclosure is executed. The method includes the following steps:
passenger data, cabin layout information and a passenger weight table of a to-be-measured flight are obtained, where the passenger data includes passenger attribute and seat attribute of each of the passengers; type of each of the passengers includes a passenger who completes seat selection and a passenger who does not complete seat selection; the seat attribute includes a seat row number of the passenger who completes seat selection; the seat row number indicates a seat row selected by the passenger; the cabin layout information includes a center of gravity index of each of the seat rows; and the passenger weight table includes a weight of a passenger corresponding to each of the passenger attributes;
a weight of the passenger who completes seat selection is determined based on the passenger weight table and the passenger attribute of the passenger who completes seat selection, and a center of gravity influence index of the passenger who completes seat selection is computed based on the seat row number, the weight and the center of gravity index of a selected seat row of the passenger who completes seat selection;
a seat is allocated to the passenger who does not complete seat selection, and a seat row number of the passenger who does not complete seat selection is obtained;
a weight of the passenger who does not complete seat selection is determined based on the passenger weight table and the passenger attribute of the passenger who does not complete seat selection, and a center of gravity influence index of the passenger who does not complete seat selection is computed based on the seat row number, the weight and the center of gravity index of a selected seat row of the passenger who does not complete seat selection; and
a center of gravity of the passengers of the to-be-measured flight is computed based on the center of gravity influence index of the passenger who completes seat selection and the center of gravity influence index of the passenger who does not complete seat selection.

Specifically, based on the example, the passenger who completes seat selection includes a checked-in passenger.

The steps that the weight of the passenger who completes seat selection is determined based on the passenger weight table and the passenger attribute of the passenger who completes seat selection, and a center of gravity influence index of the passenger who completes seat selection is computed based on the seat row number, the weight and the center of gravity index of a selected seat row of the passenger who completes seat selection include the following steps:
a weight of the checked-in passenger is obtained from the passenger weight table according to the passenger attribute of the checked-in passenger, and the center of gravity influence index of the checked-in passenger is computed based on the seat row number of the checked-in passenger, the weight of the checked-in passenger and the center of gravity index of a selected seat row of the checked-in passenger.

Specifically, based on the example, the passenger who completes seat selection further includes a passenger who does not check in but completes seat selection.

After the center of gravity influence index of the checked-in passenger is computed, the method further includes the following steps:
a weight of the passenger who does not check in but completes seat selection is obtained from the passenger weight table according to the passenger attribute of the passenger who does not check in but completes seat selection, and the center of gravity influence index of the passenger who does not check in but completes seat selection is computed based on the seat row number of the passenger who does not check in but completes seat selection, the weight of the passenger who does not check in but completes seat selection and the center of gravity index of a selected seat row of the passenger who does not check in but completes seat selection.

Specifically, based on the example, the passenger who completes seat selection further includes a stretcher passenger.

After the center of gravity influence index of the passenger who does not check in but completes seat selection is computed, the method further includes the following steps:
a weight of the stretcher passenger is obtained from a departure system, the weight of the stretcher passenger is allocated to a plurality of seat rows indicated by a seat row number of the stretcher passenger according to a preset weight allocation rule, and a weight of each of the seat rows selected by the stretcher passenger is obtained, where the preset weight allocation rule is as follows: the weight of the stretcher passenger is evenly allocated to the plurality of seat rows so as to ensure that the weight obtained by each of the seat rows is consistent, and a remaining weight is sequentially allocated to each of the seat rows in an order from smaller seat row numbers to larger seat row numbers; and
the center of gravity influence index of the stretcher passenger is computed based on the seat row number of the stretcher passenger, the weight of each of the seat rows selected by the stretcher passenger and the center of gravity index of a seat row selected by the stretcher passenger.

Specifically, based on the example, the passenger who completes seat selection further includes an extra seat occupation article.

After the center of gravity influence index of the stretcher passenger is computed, the method further includes the following steps:
a weight of the extra seat occupation article is obtained from the departure system, and the center of gravity influence index of the extra seat occupation article is computed based on the seat row number of the extra seat occupation article, the weight of the extra seat occupation article and the center of gravity index of a seat row selected by the extra seat occupation article.

Specifically, based on the example, the passenger who completes seat selection further includes a flight crew jump seat passenger.

After the center of gravity influence index of the extra seat occupation article is computed, the method further includes the following steps:
a weight of the flight crew jump seat passenger and the center of gravity influence index of a seat selected by the flight crew jump seat passenger are obtained from the departure system, and the center of gravity influence index of the flight crew jump seat passenger is computed based on the weight of the flight crew jump seat passenger and the center of gravity influence index of a seat selected by the flight crew jump seat passenger.

Specifically, based on the example, the passenger who completes seat selection further includes hand baggage.

After the center of gravity influence index of the flight crew jump seat passenger is computed, the method further includes the following steps:
a weight of the hand baggage is obtained from the departure system, and the center of gravity influence index of the hand baggage is computed based on the seat row number of the hand baggage, the weight of the hand baggage and the center of gravity index of a seat row selected by the hand baggage.

Specifically, based on the example, the method further includes the following step: the sum of the center of gravity influence index of the checked-in passenger, the center of gravity influence index of the passenger who does not check in but completes seat selection, the center of gravity influence index of the stretcher passenger, the center of gravity influence index of the extra seat occupation article, the center of gravity influence index of the flight crew jump seat passenger and the center of gravity influence index of the hand baggage is identified as the center of gravity influence index of the passenger who completes seat selection.

Specifically, based on the example, the steps that the seat is allocated to the passenger who does not complete seat selection, and the seat row number of the passenger who does not complete seat selection is obtained include the following steps:
the seat is allocated to the passenger who does not complete seat selection according to a preset passenger seat allocation rule, and the seat row number of the passenger who does not complete seat selection is obtained. The passenger seat allocation rule is as follows: for each of the seat rows, a plurality of priorities are preset for seats of the seat row, and a number of seats in each of the priorities is limited, such that the sum of the numbers of the seats in all the priorities equals a number of the seats of the seat row. A number of first seats included in the seat row is counted, and the number of the first seats of the seat row is obtained. In a case that the number of the first seats is smaller than that of the seats of the seat row, a seat row number and a priority of second seats included in the seat row are obtained. For the second seats included in each of the seat rows, in an order from higher priorities to lower priorities and an order from smaller seat row numbers to larger seat row numbers, each of the second seats is identified as a positive-sequence seat and allocated to each passenger who does not complete seat selection. According to the order from higher priorities to lower priorities and an order from larger seat row numbers to smaller seat row numbers, each of the second seats is identified as a negative-sequence seat and allocated to each passenger who does not complete seat selection. The first seats represent seats selected by the passengers. The second seats represent seats not selected by the passengers.

Although the subject matter is described in languages of specific structural features and/or methodological logic actions, it should be understood that the subject matter defined in the appended claims is not necessarily limited to the specific features or actions described above. On the contrary, the specific features and actions described above are merely illustrative forms for implementing the claims.

Although several specific implementation details are included in the above discussion, the details should not be construed as limiting the scope of the present disclosure. Some features described in the context of separate examples may also be implemented in combination in a single example. On the contrary, various features described in the context of a single example may also be implemented in a plurality of examples independently or in any suitable sub-combination manner.

What are described above are merely illustrative of preferred examples of the present disclosure and of principles of the technology employed. Those skilled in the art should understand that the present disclosure scope of the present disclosure is not limited to the technical solution formed by a specific combination of the technical features described above, and should further cover other technical solutions formed by any combination of the technical features described above or their equivalent features without departing from the disclosed concept, and for instance, the technical solution formed by interchanging the features with the technical features with similar functions disclosed in (but not limited to) the present disclosure.

1. A method for estimating a center of gravity of flight passengers, comprising:
determining, based on a passenger weight table and a passenger attribute of a passenger who completes seat selection, a weight of the passenger who completes seat selection, and computing, based on a seat row number, the weight and a center of gravity index of a selected seat row of the passenger who completes seat selection, a center of gravity influence index of the passenger who completes seat selection;
allocating, based on a preset seat priority and a current number of remaining seats in each priority, a seat to a passenger who does not complete seat selection through combination of a positive-sequence allocation manner and a negative-sequence allocation manner, and obtaining a seat row number of the passenger who does not complete seat selection;
determining, based on the passenger weight table and the passenger attribute of the passenger who does not complete seat selection, a weight of the passenger who does not complete seat selection, and computing, based on the seat row number, the weight and the center of gravity index of a selected seat row of the passenger who does not complete seat selection, a center of gravity influence index of the passenger who does not complete seat selection; and
computing a center of gravity of the passengers of a to-be-measured flight based on the center of gravity influence index of the passenger who completes seat selection and the center of gravity influence index of the passenger who does not complete seat selection.

2. The method according to claim 11, wherein the passenger who completes seat selection comprises a checked-in passenger; and
the determining, based on the passenger weight table and the passenger attribute of the passenger who completes seat selection, a weight of the passenger who completes seat selection, and computing, based on the seat row number, the weight and the center of gravity index of a selected seat row of the passenger who completes seat selection, a center of gravity influence index of the passenger who completes seat selection comprise:
obtaining a weight of the checked-in passenger from the passenger weight table according to the passenger attribute of the checked-in passenger, and computing, based on the seat row number of the checked-in passenger, the weight of the checked-in passenger and the center of gravity index of a selected seat row of the checked-in passenger, the center of gravity influence index of the checked-in passenger.

3. The method according to claim 2, wherein the passenger who completes seat selection further comprises a passenger who does not check in but completes seat selection; and
after the computing the center of gravity influence index of the checked-in passenger, the method further comprises:
obtaining a weight of the passenger who does not check in but completes seat selection from the passenger weight table according to the passenger attribute of the passenger who does not check in but completes seat selection, and computing, based on the seat row number of the passenger who does not check in but completes seat selection, the weight of the passenger who does not check in but completes seat selection and the center of gravity index of a selected seat row of the passenger who does not check in but completes seat selection, the center of gravity influence index of the passenger who does not check in but completes seat selection.

4. The method according to claim 3, wherein the passenger who completes seat selection further comprises a stretcher passenger; and
after the computing the center of gravity influence index of the passenger who does not check in but completes seat selection, the method further comprises:
obtaining a weight of the stretcher passenger from a departure system, allocating the weight of the stretcher passenger to a plurality of seat rows indicated by the seat row number of the stretcher passenger according to a preset weight allocation rule, and obtaining a weight of each of the seat rows selected by the stretcher passenger, wherein the preset weight allocation rule is as follows: allocating the weight of the stretcher passenger evenly to the plurality of seat rows so as to ensure that the weight obtained by each of the seat rows is consistent, and sequentially allocating a remaining weight to each of the seat rows in an order from smaller seat row numbers to larger seat row numbers; and
computing, based on the seat row number of the stretcher passenger, the weight of each of the seat rows selected by the stretcher passenger and the center of gravity index of a seat row selected by the stretcher passenger, the center of gravity influence index of the stretcher passenger.

5. The method according to claim 4, wherein the passenger who completes seat selection further comprises an extra seat occupation article; and
after the computing the center of gravity influence index of the stretcher passenger, the method further comprises:
obtaining a weight of the extra seat occupation article from the departure system, and computing, based on the seat row number of the extra seat occupation article, the weight of the extra seat occupation article and the center of gravity index of a seat row selected by the extra seat occupation article, the center of gravity influence index of the extra seat occupation article.

6. The method according to claim 5, wherein the passenger who completes seat selection further comprises a flight crew jump seat passenger; and
after the computing the center of gravity influence index of the extra seat occupation article, the method further comprises:
obtaining a weight of the flight crew jump seat passenger and the center of gravity influence index of a seat selected by the flight crew jump seat passenger from the departure system, and computing, based on the weight of the flight crew jump seat passenger and the center of gravity influence index of the seat selected by the flight crew jump seat passenger, the center of gravity influence index of the flight crew jump seat passenger.

7. The method according to claim 6, wherein the passenger who completes seat selection further comprises hand baggage; and
after the computing the center of gravity influence index of the flight crew jump seat passenger, the method further comprises:
obtaining a weight of the hand baggage from the departure system, and computing, based on the seat row number of the hand baggage, the weight of the hand baggage and the center of gravity index of a seat row selected by the hand baggage, the center of gravity influence index of the hand baggage.

8. The method according to claim 7, further comprising:
identifying the sum of the center of gravity influence index of the checked-in passenger, the center of gravity influence index of the passenger who does not check in but completes seat selection, the center of gravity influence index of the stretcher passenger, the center of gravity influence index of the extra seat occupation article, the center of gravity influence index of the flight crew jump seat passenger and the center of gravity influence index of the hand baggage as the center of gravity influence index of the passenger who completes seat selection.

9. The method according to claim 411, wherein the allocating a seat to the passenger who does not complete seat selection, and obtaining a seat row number of the passenger who does not complete seat selection comprise:
allocating the seat to the passenger who does not complete seat selection according to a preset passenger seat allocation rule, and obtaining the seat row number of the passenger who does not complete seat selection, wherein the passenger seat allocation rule is as follows: for each of the seat rows, presetting a plurality of priorities for seats of the seat row, and limiting a number of seats in each of the priorities, such that the sum of the numbers of the seats in all the priorities equals a number of the seats of the seat row; counting a number of first seats comprised in the seat row, and obtaining the number of the first seats of the seat row; in a case that the number of the first seats is smaller than that of the seats of the seat row, obtaining a seat row number and a priority of second seats comprised in the seat row; for the second seats comprised in each of the seat rows, in an order from higher priorities to lower priorities and an order from smaller seat row numbers to larger seat row numbers, identifying each of the second seats as a positive-sequence seat and allocating each of the second seats to each passenger who does not complete seat selection; in the order from higher priorities to lower priorities and an order from larger seat row numbers to smaller seat row numbers, identifying each of the second seats as a negative-sequence seat and allocating each of the second seats to each passenger who does not complete seat selection; representing the first seats as seats selected by the passengers; and representing the second seats as seats not selected by the passengers.

10. An apparatus for estimating a center of gravity of flight passengers, comprising:
a first determination unit configured to determine, based on a passenger weight table and a passenger attribute of a passenger who completes seat selection, a weight of the passenger who completes seat selection, and compute, based on a seat row number, the weight and a center of gravity index of a selected seat row of the passenger who completes seat selection, a center of gravity influence index of the passenger who completes seat selection;
a seat allocation unit configured to allocate, based on a preset seat priority and a current number of remaining seats in each priority, a seat to a passenger who does not complete seat selection through combination of a positive-sequence allocation manner and a negative-sequence allocation manner, and obtain a seat row number of the passenger who does not complete seat selection;
a second determination unit configured to determine, based on the passenger weight table and the passenger attribute of the passenger who does not complete seat selection, a weight of the passenger who does not complete seat selection, and compute, based on the seat row number, the weight and the center of gravity index of a selected seat row of the passenger who does not complete seat selection, a center of gravity influence index of the passenger who does not complete seat selection; and
a center of gravity computation unit configured to compute a center of gravity of the passengers of a to-be-measured flight based on the center of gravity influence index of the passenger who completes seat selection and the center of gravity influence index of the passenger who does not complete seat selection.

11. The method according to claim 1, wherein before determining, based on a passenger weight table and a passenger attribute of a passenger who completes seat selection, a weight of the passenger who completes seat selection, the method further comprises:
obtaining passenger data, cabin layout information and the passenger weight table of the to-be-measured flight, wherein the passenger data comprises passenger attribute and seat attribute of each of the passengers; type of each of the passengers comprises the passenger who completes seat selection and the passenger who does not complete seat selection; the seat attribute comprises the seat row number and a seat number of the passenger who completes seat selection; the seat row number indicates a seat row selected by the passenger; the seat number indicates a seat selected by the passenger; the cabin layout information comprises the center of gravity index of each of the seat rows; the passenger weight table comprises a weight of a passenger corresponding to each of the passenger attributes; and types of the passenger attribute comprise an adult passenger, a male passenger, a female passenger, a child passenger, and an infant passenger;

12. A device for estimating a center of gravity of flight passengers, comprising: a processor, a memory, and a bus, wherein the processor is connected to the memory through the bus, the memory is configured to store a program, the processor is configured to run a program, when the program runs, following actions are executed:
determining, based on a passenger weight table and a passenger attribute of a passenger who completes seat selection, a weight of the passenger who completes seat selection, and computing, based on a seat row number, the weight and a center of gravity index of a selected seat row of the passenger who completes seat selection, a center of gravity influence index of the passenger who completes seat selection;
allocating, based on a preset seat priority and a current number of remaining seats in each priority, a seat to a passenger who does not complete seat selection through combination of a positive-sequence allocation manner and a negative-sequence allocation manner, and obtaining a seat row number of the passenger who does not complete seat selection;
determining, based on the passenger weight table and the passenger attribute of the passenger who does not complete seat selection, a weight of the passenger who does not complete seat selection, and computing, based on the seat row number, the weight and the center of gravity index of a selected seat row of the passenger who does not complete seat selection, a center of gravity influence index of the passenger who does not complete seat selection; and
computing a center of gravity of the passengers of a to-be-measured flight based on the center of gravity influence index of the passenger who completes seat selection and the center of gravity influence index of the passenger who does not complete seat selection.
